(19) United States
(12) Patent Application Publication
(10) Pub. No.: US 2021/0320643 A1
(43) Pub. Date: Oct. 14, 2021

(54) PIEZOELECTRIC RESONATOR TEMPERATURE DETERMINATION

(71) Applicant: QUALCOMM INCORPORATED, San Diego, CA (US)

(72) Inventor: Duong HOANG, San Diego, CA (US)

(21) Appl. No.: 16/844,774

(22) Filed: Apr. 9, 2020

(51) Int. Cl. H03H 9/17; H03H 9/02

(52) U.S. Cl. CPC H03H 9/17; H03H 9/02102

(57) ABSTRACT

A mobile device includes: a printed circuit board including circuit components and a plurality of traces that are electrically and thermally conductive; a piezoelectric resonator coupled to a subset of the traces by a plurality of connectors that are electrically and thermally conductive; a temperature sensor configured to provide an indication of temperature; and a thermal coupler coupled to the temperature sensor and to the plurality of connectors, the thermal coupler being thermally conductive and electrically insulative.

### BACKGROUND

Many devices today include satellite navigation system (SPS) capabilities for determining location of the devices. For example, mobile phones, smartphones, smartwatches, laptop computers, tablet computers, etc. may use signals from the Global Positioning System (GPS), or other SPS, to help determine location.

To acquire and track SPS signals, an oscillation frequency from an oscillator is used. To generate this frequency signal, a piezoelectric resonator, also known as a crystal, is often used. Crystals, however, produce signals whose frequencies may vary with temperature. Changes in temperature of the crystals, therefore, may inhibit the ability of the device using the crystal to acquire and track the SPS signals. While crystals are useful to acquire and track SPS signals, crystals have uses beyond acquiring and tracking SPS signals and in devices other than mobile devices.

Various techniques have been used to try to determine the temperature of a crystal, including changes in temperature of a crystal, in order to determine the actual frequency of a signal produced by the crystal and to compensate for the actual frequency relative to a baseline frequency, e.g., at a baseline temperature. For example, devices have been made with a temperature sensor disposed proximate to a crystal and experimental data used to determine a relationship between sensed temperature and temperature of the crystal. As another example, devices have been made with multiple temperature sensors disposed within a device, e.g., where the device includes multiple heat sources affecting a temperature of a crystal. The multiple temperature sensors may be placed around the crystal and/or proximate to the sources of heat affecting the crystal. A relationship between multiple sensed temperatures and the temperature of the crystal may be used to determine, and compensate for, temperature-dependent frequency of the crystal.

### SUMMARY

An example mobile device includes: a printed circuit board including circuit components and a plurality of traces that are electrically and thermally conductive; a piezoelectric resonator coupled to a subset of the traces by a plurality of connectors that are electrically and thermally conductive; a temperature sensor configured to provide an indication of temperature; and a thermal coupler coupled to the temperature sensor and to the plurality of connectors, the thermal coupler being thermally conductive and electrically insulative.

Implementations of such a mobile device may include one or more of the following features. The thermal coupler is configured and disposed to thermally couple at least two of the plurality of connectors to each other. The thermal coupler is configured and disposed to thermally couple all of the plurality of connectors to each other. The thermal coupler is configured and disposed to thermally couple each of the plurality of connectors to the temperature sensor separately. The temperature sensor is in physical contact with the piezoelectric resonator. The temperature sensor is disposed adjacent to, and separate from, the piezoelectric resonator. At least a portion of the temperature sensor is disposed between the printed circuit board and the piezoelectric resonator. The temperature sensor is configured and connected to the thermal coupler to provide a single measure of temperature corresponding to heat received from the thermal coupler. The mobile device includes a processor communicatively coupled to the temperature sensor and configured to determine a frequency of the piezoelectric resonator based on the indication of temperature.

An example method includes: transferring heat through a plurality of traces of a printed circuit board to a plurality of connectors that are connected to a piezoelectric resonator, the plurality of traces being electrically and thermally conductive, and the plurality of connectors being electrically and thermally conductive; transferring a portion of the heat from the plurality of connectors through a thermally-conductive, electrically-insulative material to a temperature sensor; and providing an indication of temperature by the temperature sensor.

Implementations of such a method may include one or more of the following features. The portion of the heat is transferred from the plurality of connectors to a single input of the temperature sensor. The temperature sensor provides a single measure of temperature corresponding to the portion of the heat transferred to the temperature sensor. The method includes determining a frequency of the piezoelectric resonator based on the indication of temperature.

An example apparatus includes: a piezoelectric resonator; temperature means for measuring, and providing an indication of, temperature; means for transferring heat from a plurality of heat sources of a printed circuit board to a plurality of connectors that are connected to the piezoelectric resonator, the plurality of connectors being electrically and thermally conductive; and thermal means for transferring a portion of the heat from the plurality of connectors to the temperature means, the thermal means being thermally conductive and electrically insulative.

Implementations of such an apparatus may include one or more of the following features. The plurality of connectors includes at least three connectors and the thermal means thermally couple at least two of the plurality of connectors to each other. The thermal means thermally couple all of the plurality of connectors to each other. The thermal means thermally couple each of the plurality of connectors to the temperature means separately. The temperature means are in physical contact with the piezoelectric resonator. The temperature means are disposed adjacent to, and separate from, the piezoelectric resonator. At least a portion of the temperature means is disposed between the printed circuit board and the piezoelectric resonator. The thermal means are for transferring the portion of the heat from the plurality of connectors to a single input of the temperature means. The apparatus includes means, communicatively coupled to the temperature means, for determining a frequency of the piezoelectric resonator based on the indication of temperature.

### BRIEF DESCRIPTION OF THE DRAWINGS

FIG. 1 is a schematic view of a telecommunication and positioning system.

FIG. 2 is an exploded perspective view of an example mobile device shown in FIG. 1.

FIG. 3 is a block diagram of the mobile device shown in FIG. 2.

FIGS. 4 and 5 are block diagrams of portions of the mobile device shown in FIG. 3.

FIGS. 6-8 are side views of example configurations of a crystal, a temperature sensor, and various configurations of thermal couplers of the mobile device shown in FIG. 3.

FIG. 9 is a block flow diagram of a method of providing an indication of a temperature associated with a piezoelectric resonator.

### DETAILED DESCRIPTION

As used herein, a mobile terminal (MT), sometimes referred to as a mobile device, a mobile station (MS) or user equipment (UE), is a device such as a cellular phone, mobile phone or other wireless communication device, personal communication system (PCS) device, personal navigation device (PND), Personal Information Manager (PIM), Personal Digital Assistant (PDA), laptop, wearables (e.g., smartwatches, smart glasses, etc.) or other suitable mobile device which is capable of receiving wireless communication and/or navigation signals. The term mobile terminal includes devices that communicate with a personal navigation device (PND), such as by short-range wireless, infrared, wireline connection, or other connection—regardless of whether satellite signal reception, assistance data reception, and/or position-related processing occurs at the device or at the PND. Also, the term mobile terminal includes devices, including wireless communication devices, computers, laptops, etc. that are capable of communication with a server, such as via the Internet, WiFi, or other network, and regardless of whether satellite signal reception, assistance data reception, and/or position-related processing occurs at the device, at a server, or at another device associated with the network. Any operable combination of the above are also considered a mobile terminal.

Techniques are provided to determine, and compensate for, changes in a reference frequency provided by a piezoelectric resonator (also called a crystal) as part of a crystal oscillator. For example, a temperature of a piezoelectric resonator is monitored. Electrically-conductive pins connecting the piezoelectric resonator to a traces of a printed circuit board are (e.g., thermally) coupled to a temperature sensor. For example, the pins may be thermally coupled to an input of the temperature sensor, and the temperature sensor may provide an indication of temperature associated with (e.g., that is indicative of) a temperature of the piezoelectric resonator. The temperature associated with the piezoelectric resonator, and an effect on a temperature of the piezoelectric resonator due to temperature changes of the at least one module, are used to estimate crystal oscillator frequency or a change in crystal oscillator frequency. This estimated crystal oscillator frequency or change in crystal oscillator frequency is used to compensate for the temperature-affected frequency, e.g., is used to adjust signal processing such as acquiring or maintaining a fix on a satellite signal.

Items and/or techniques described herein may provide one or more of the following capabilities, as well as other capabilities not mentioned. Temperatures of a crystal of a crystal oscillator may be more accurately determined by thermally coupling connectors of the crystal to a temperature sensor. Temperatures of a crystal of a crystal oscillator may be accurately determined regardless of a number of heat sources. Temperatures of a crystal of a crystal oscillator may be accurately determined regardless of locations of heat sources relative to the crystal and/or relative to a temperature sensor location relative to the crystal. Changes in crystal temperature may be determined more accurately and quicker than with previous configurations, i.e., a lag between a change in crystal temperature and a change in estimated crystal temperature may be reduced compared to previous techniques. A reference frequency provided by a crystal of a crystal oscillator may be more accurately determined by accounting for heat transfer between the crystal and one or more other components thermally connected to the crystal. Temperature and corresponding frequency of a crystal of a crystal oscillator may be determined more accurately in view of multiple heat sources thermally connected to the crystal. Temperature and corresponding frequency of a crystal of a crystal oscillator may be determined with fewer temperature sensors than sources of heat affecting the crystal. For example, a single temperature sensor may be used despite multiple heat sources heating the crystal. A location of the single temperature sensor may be independent of locations of the heat sources. A relationship between a sensed temperature and estimated crystal temperature may be uncomplicated despite multiple sources of heat affecting temperature of the crystal. Processing power for estimating actual crystal frequency in view of crystal heating may be kept low, e.g., due to the uncomplicated relationship between sensed temperature and estimated crystal temperature. Other capabilities may be provided and not every implementation according to the disclosure must provide any, let alone all, of the capabilities discussed.

The description may refer to sequences of actions to be performed, for example, by elements of a computing device. Various actions described herein can be performed by specific circuits (e.g., an application specific integrated circuit (ASIC)), by program instructions being executed by one or more processors, or by a combination of both. Sequences of actions described herein may be embodied within a non-transitory computer-readable medium having stored thereon a corresponding set of computer instructions that upon execution would cause an associated processor to perform the functionality described herein. Thus, the various aspects described herein may be embodied in a number of different forms, all of which are within the scope of the disclosure, including claimed subject matter.

As used herein, the terms “user equipment” (UE) and “base station” are not specific to or otherwise limited to any particular Radio Access Technology (RAT), unless otherwise noted. In general, such UEs may be any wireless communication device (e.g., a mobile phone, router, tablet computer, laptop computer, tracking device, Internet of Things (IoT) device, etc.) used by a user to communicate over a wireless communications network. A UE may be mobile or may (e.g., at certain times) be stationary, and may communicate with a Radio Access Network (RAN). As used herein, the term “UE” may be referred to interchangeably as an “access terminal” or “AT,” a “client device,” a “wireless device,” a “subscriber device,” a “subscriber terminal,” a “subscriber station,” a “user terminal” or UT, a “mobile terminal,” a “mobile station,” or variations thereof. Generally, UEs can communicate with a core network via a RAN, and through the core network the UEs can be connected with external networks such as the Internet and with other UEs. Of course, other mechanisms of connecting to the core network and/or the Internet are also possible for the UEs, such as over wired access networks, WiFi networks (e.g., based on IEEE 802.11, etc.) and so on.

A base station may operate according to one of several RATs in communication with UEs depending on the network in which it is deployed, and may be alternatively referred to as an Access Point (AP), a Network Node, a NodeB, an evolved NodeB (eNB), a general Node B (gNodeB, gNB), etc. In addition, in some systems a base station may provide purely edge node signaling functions while in other systems it may provide additional control and/or network management functions.

UEs may be embodied by any of a number of types of devices including but not limited to printed circuit (PC) cards, compact flash devices, external or internal modems, wireless or wireline phones, smartphones, tablets, tracking devices, asset tags, and so on. A communication link through which UEs can send signals to a RAN is called an uplink channel (e.g., a reverse traffic channel, a reverse control channel, an access channel, etc.). A communication link through which the RAN can send signals to UEs is called a downlink or forward link channel (e.g., a paging channel, a control channel, a broadcast channel, a forward traffic channel, etc.). As used herein the term traffic channel (TCH) can refer to either an uplink/reverse or downlink/forward traffic channel.

As used herein, the term “cell” or “sector” may correspond to one of a plurality of cells of a base station, or to the base station itself, depending on the context. The term “cell” may refer to a logical communication entity used for communication with a base station (for example, over a carrier), and may be associated with an identifier for distinguishing neighboring cells (for example, a physical cell identifier (PCID), a virtual cell identifier (VCID)) operating via the same or a different carrier. In some examples, a carrier may support multiple cells, and different cells may be configured according to different protocol types (for example, machine-type communication (MTC), narrowband Internet-of-Things (NB-IoT), enhanced mobile broadband (eMBB), or others) that may provide access for different types of devices. In some examples, the term “cell” may refer to a portion of a geographic coverage area (for example, a sector) over which the logical entity operates.

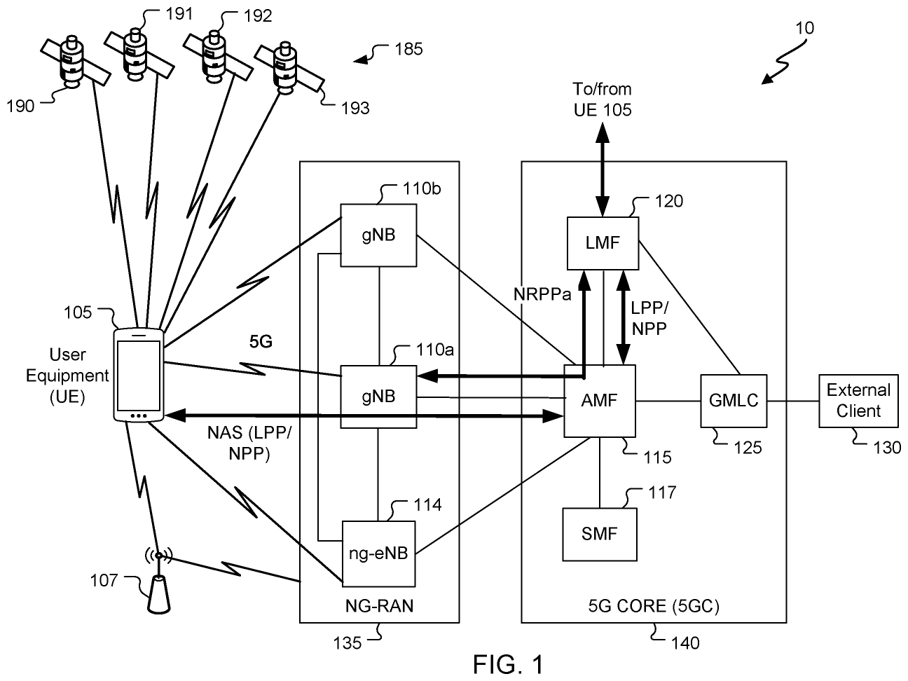

Referring to FIG. 1, an example of a telecommunication and positioning system 10 includes a UE 105, a Wi-Fi access point (AP) 107, a Radio Access Network (RAN) 135, here a Fifth Generation (5G) Next Generation (NG) RAN (NG-RAN), and a 5G Core Network (5GC) 140. The UE 105 may be, e.g., an IoT device, a location tracker device, a cellular telephone, or other device. A 5G network may also be referred to as a New Radio (NR) network; NG-RAN 135 may be referred to as a 5G RAN or as an NR RAN; and 5GC 140 may be referred to as an NG Core network (NGC). Standardization of an NG-RAN and 5GC is ongoing in the 3rd Generation Partnership Project (3GPP). Accordingly, the NG-RAN 135 and the 5GC 140 may conform to current or future standards for 5G support from 3GPP. The RAN 135 may be another type of RAN, e.g., a 3G RAN, a 4G Long Term Evolution (LTE) RAN, etc. The communication system 10 may utilize information from a constellation 185 of satellite vehicles (SVs) 190, 191, 192, 193 for a Satellite Positioning System (SPS) (e.g., a Global Navigation Satellite System (GNSS)) like the Global Positioning System (GPS), the Global Navigation Satellite System (GLONASS), Galileo, or Beidou or some other local or regional SPS such as the Indian Regional Navigational Satellite System (IRNSS), the European Geostationary Navigation Overlay Service (EGNOS), or the Wide Area Augmentation System (WAAS). Additional components of the communication system 10 are described below. The WiFi AP 107 and the UE 105 are configured to communicate with each other bi-directionally, and the WiFi AP 107 may be considered to be part of the NG-RAN 135. While one WiFi AP is shown in FIG. 1, the communication system 10 may include more than one WiFi AP, or no WiFi APs. The communication system 10 may include additional or alternative components.

As shown in FIG. 1, the NG-RAN 135 includes NR nodeBs (gNBs) 110a, 110b, and a next generation eNodeB (ng-eNB) 114, and the 5GC 140 includes an Access and Mobility Management Function (AMF) 115, a Session Management Function (SMF) 117, a Location Management Function (LMF) 120, and a Gateway Mobile Location Center (GMLC) 125. The gNBs 110a, 110b and the ng-eNB 114 are communicatively coupled to each other, are each configured to bi-directionally wirelessly communicate with the UE 105, and are each communicatively coupled to, and configured to bi-directionally communicate with, the AMF 115. The AMF 115, the SMF 117, the LMF 120, and the GMLC 125 are communicatively coupled to each other, and the GMLC is communicatively coupled to an external client 130. The SMF 117 may serve as an initial contact point of a Service Control Function (SCF) (not shown) to create, control, and delete media sessions.

FIG. 1 provides a generalized illustration of various components, any or all of which may be utilized as appropriate, and each of which may be duplicated or omitted as necessary. Specifically, although only one UE 105 is illustrated, many UEs (e.g., hundreds, thousands, millions, etc.) may be utilized in the communication system 10. Similarly, the communication system 10 may include a larger (or smaller) number of SVs (i.e., more or fewer than the four SVs 190-193 shown), gNBs 110a, 110b, ng-eNBs 114, AMFs 115, external clients 130, and/or other components. The illustrated connections that connect the various components in the communication system 10 include data and signaling connections which may include additional (intermediary) components, direct or indirect physical and/or wireless connections, and/or additional networks. Furthermore, components may be rearranged, combined, separated, substituted, and/or omitted, depending on desired functionality.

While FIG. 1 illustrates a 5G-based network, similar network implementations and configurations may be used for other communication technologies, such as 3G, Long Term Evolution (LTE), etc. Implementations described herein (be they for 5G technology and/or for one or more other communication technologies and/or protocols) may be used to transmit (or broadcast) directional synchronization signals, receive and measure directional signals at UEs (e.g., the UE 105) and/or provide location assistance to the UE 105 (via the GMLC 125 or other location server) and/or compute a location for the UE 105 at a location-capable device such as the UE 105, the gNB 110a, 110b, or the LMF 120 based on measurement quantities received at the UE 105 for such directionally-transmitted signals. The gateway mobile location center (GMLC) 125, the location management function (LMF) 120, the access and mobility management function (AMF) 115, the SMF 117, the ng-eNB (eNodeB) 114 and the gNBs (gNodeBs) 110a, 110b are examples and may, in various embodiments, be replaced by or include various other location server functionality and/or base station functionality respectively.

The UE 105 may comprise and/or may be referred to as a device, a mobile device, a wireless device, a mobile terminal, a terminal, a mobile station (MS), a Secure User Plane Location (SUPL) Enabled Terminal (SET), or by some other name. Moreover, the UE 105 may correspond to a cellphone, smartphone, laptop, tablet, PDA, tracking device, navigation device, Internet of Things (IoT) device, asset tracker, health monitors, security systems, smart city sensors, smart meters, wearable trackers, or some other portable or moveable device. Typically, though not necessarily, the UE 105 may support wireless communication using one or more Radio Access Technologies (RATs) such as Global System for Mobile communication (GSM), Code Division Multiple Access (CDMA), Wideband CDMA (WCDMA), LTE, High Rate Packet Data (HRPD), IEEE 802.11 WiFi (also referred to as Wi-Fi), Bluetooth® (BT), Worldwide Interoperability for Microwave Access (WiMAX), 5G new radio (NR) (e.g., using the NG-RAN 135 and the 5GC 140), etc. The UE 105 may support wireless communication using a Wireless Local Area Network (WLAN) which may connect to other networks (e.g., the Internet) using a Digital Subscriber Line (DSL) or packet cable, for example. The use of one or more of these RATs may allow the UE 105 to communicate with the external client 130 (e.g., via elements of the 5GC 140 not shown in FIG. 1, or possibly via the GMLC 125) and/or allow the external client 130 to receive location information regarding the UE 105 (e.g., via the GMLC 125).

The UE 105 may include a single entity or may include multiple entities such as in a personal area network where a user may employ audio, video and/or data I/O (input/output) devices and/or body sensors and a separate wireline or wireless modem. An estimate of a location of the UE 105 may be referred to as a location, location estimate, location fix, fix, position, position estimate, or position fix, and may be geographic, thus providing location coordinates for the UE 105 (e.g., latitude and longitude) which may or may not include an altitude component (e.g., height above sea level, height above or depth below ground level, floor level, or basement level). Alternatively, a location of the UE 105 may be expressed as a civic location (e.g., as a postal address or the designation of some point or small area in a building such as a particular room or floor). A location of the UE 105 may be expressed as an area or volume (defined either geographically or in civic form) within which the UE 105 is expected to be located with some probability or confidence level (e.g., 67%, 95%, etc.). A location of the UE 105 may be expressed as a relative location comprising, for example, a distance and direction from a known location. The relative location may be expressed as relative coordinates (e.g., X, Y (and Z) coordinates) defined relative to some origin at a known location which may be defined, e.g., geographically, in civic terms, or by reference to a point, area, or volume, e.g., indicated on a map, floor plan, or building plan. In the description contained herein, the use of the term location may comprise any of these variants unless indicated otherwise. When computing the location of a UE, it is common to solve for local x, y, and possibly z coordinates and then, if desired, convert the local coordinates into absolute coordinates (e.g., for latitude, longitude, and altitude above or below mean sea level).

The UE 105 may be configured to communicate with other entities using one or more of a variety of technologies. The UE 105 may be configured to connect indirectly to one or more communication networks via one or more device-to-device (D2D) peer-to-peer (P2P) links. The D2D P2P links may be supported with any appropriate D2D radio access technology (RAT), such as LTE Direct (LTE-D), WiFi Direct (WiFi-D), Bluetooth®, and so on. One or more of a group of UEs utilizing D2D communications may be within a geographic coverage area of a Transmission/Reception Point (TRP) such as one or more of the gNBs 110a, 110b, and/or the ng-eNB 114. Other UEs in such a group may be outside such geographic coverage areas, or may be otherwise unable to receive transmissions from a base station. Groups of UEs communicating via D2D communications may utilize a one-to-many (1:M) system in which each UE may transmit to other UEs in the group. A TRP may facilitate scheduling of resources for D2D communications. In other cases, D2D communications may be carried out between UEs without the involvement of a TRP.

Base stations (BSs) in the NG-RAN 135 shown in FIG. 1 include NR Node Bs, referred to as the gNBs 110a and 110b. Pairs of the gNBs 110a, 110b in the NG-RAN 135 may be connected to one another via one or more other gNBs. Access to the 5G network is provided to the UE 105 via wireless communication between the UE 105 and one or more of the gNBs 110a, 110b, which may provide wireless communications access to the 5GC 140 on behalf of the UE 105 using 5G. In FIG. 1, the serving gNB for the UE 105 is assumed to be the gNB 110a, although another gNB (e.g. the gNB 110b) may act as a serving gNB if the UE 105 moves to another location or may act as a secondary gNB to provide additional throughput and bandwidth to the UE 105.

Base stations (BSs) in the NG-RAN 135 shown in FIG. 1 may include the ng-eNB 114, also referred to as a next generation evolved Node B. The ng-eNB 114 may be connected to one or more of the gNBs 110a, 110b in the NG-RAN 135, possibly via one or more other gNBs and/or one or more other ng-eNBs. The ng-eNB 114 may provide LTE wireless access and/or evolved LTE (eLTE) wireless access to the UE 105. One or more of the gNBs 110a, 110b and/or the ng-eNB 114 may be configured to function as positioning-only beacons which may transmit signals to assist with determining the position of the UE 105 but may not receive signals from the UE 105 or from other UEs.

The BSs 110a, 110b, 114 may each comprise one or more TRPs. For example, each sector within a cell of a BS may comprise a TRP, although multiple TRPs may share one or more components (e.g., share a processor but have separate antennas). The system 10 may include only macro TRPs or the system 10 may have TRPs of different types, e.g., macro, pico, and/or femto TRPs, etc. A macro TRP may cover a relatively large geographic area (e.g., several kilometers in radius) and may allow unrestricted access by terminals with service subscription. A pico TRP may cover a relatively small geographic area (e.g., a pico cell) and may allow unrestricted access by terminals with service subscription. A femto or home TRP may cover a relatively small geographic area (e.g., a femto cell) and may allow restricted access by terminals having association with the femto cell (e.g., terminals for users in a home).

As noted, while FIG. 1 depicts nodes configured to communicate according to 5G communication protocols, nodes configured to communicate according to other communication protocols, such as, for example, an LTE protocol or IEEE 802.11x protocol, may be used. For example, in an Evolved Packet System (EPS) providing LTE wireless access to the UE 105, a RAN may comprise an Evolved Universal Mobile Telecommunications System (UMTS) Terrestrial Radio Access Network (E-UTRAN) which may comprise base stations comprising evolved Node Bs (eNBs). A core network for EPS may comprise an Evolved Packet Core (EPC). An EPS may comprise an E-UTRAN plus EPC, where the E-UTRAN corresponds to the NG-RAN 135 and the EPC corresponds to the 5GC 140 in FIG. 1.

The gNBs 110a, 110b and the ng-eNB 114 may communicate with the AMF 115, which, for positioning functionality, communicates with the LMF 120. The AMF 115 may support mobility of the UE 105, including cell change and handover and may participate in supporting a signaling connection to the UE 105 and possibly data and voice bearers for the UE 105. The LMF 120 may communicate directly with the UE 105, e.g., through wireless communications. The LMF 120 may support positioning of the UE 105 when the UE 105 accesses the NG-RAN 135 and may support position procedures/methods such as Assisted GNSS (A-GNSS), Observed Time Difference of Arrival (OTDOA), Real Time Kinematics (RTK), Precise Point Positioning (PPP), Differential GNSS (DGNSS), Enhanced Cell ID (E-CID), angle of arrival (AOA), angle of departure (AOD), and/or other position methods. The LMF 120 may process location services requests for the UE 105, e.g., received from the AMF 115 or from the GMLC 125. The LMF 120 may be connected to the AMF 115 and/or to the GMLC 125. The LMF 120 may be referred to by other names such as a Location Manager (LM), Location Function (LF), commercial LMF (CLMF), or value added LMF (VLMF). A node/system that implements the LMF 120 may additionally or alternatively implement other types of location-support modules, such as an Enhanced Serving Mobile Location Center (E-SMLC) or a Secure User Plane Location (SUPL) Location Platform (SLP). At least part of the positioning functionality (including derivation of the UE 105's location) may be performed at the UE 105 (e.g., using signal measurements obtained by the UE 105 for signals transmitted by wireless nodes such as the gNBs 110a, 110b and/or the ng-eNB 114, and/or assistance data provided to the UE 105, e.g. by the LMF 120).

The GMLC 125 may support a location request for the UE 105 received from the external client 130 and may forward such a location request to the AMF 115 for forwarding by the AMF 115 to the LMF 120 or may forward the location request directly to the LMF 120. A location response from the LMF 120 (e.g., containing a location estimate for the UE 105) may be returned to the GMLC 125 either directly or via the AMF 115 and the GMLC 125 may then return the location response (e.g., containing the location estimate) to the external client 130. The GMLC 125 is shown connected to both the AMF 115 and LMF 120, though only one of these connections may be supported by the 5GC 140 in some implementations.

As further illustrated in FIG. 1, the LMF 120 may communicate with the gNBs 110a, 110b and/or hte ng-eNB 114 using a New Radio Position Protocol A (which may be referred to as NPPa or NRPPa), which may be defined in 3GPP Technical Specification (TS) 38.455. NRPPa may be the same as, similar to, or an extension of the LTE Positioning Protocol A (LPPa) defined in 3GPP TS 36.455, with NRPPa messages being transferred between the gNB 110a (or the gNB 110b) and the LMF 120, and/or between the ng-eNB 114 and the LMF 120, via the AMF 115. As further illustrated in FIG. 1, the LMF 120 and the UE 105 may communicate using an LTE Positioning Protocol (LPP), which may be defined in 3GPP TS 36.355. The LMF 120 and the UE 105 may also or instead communicate using a New Radio Positioning Protocol (which may be referred to as NPP or NRPP), which may be the same as, similar to, or an extension of LPP. Here, LPP and/or NPP messages may be transferred between the UE 105 and the LMF 120 via the AMF 115 and the serving gNB 110a, 110b or the serving ng-eNB 114 for the UE 105. For example, LPP and/or NPP messages may be transferred between the LMF 120 and the AMF 115 using a 5G Location Services Application Protocol (LCS AP) and may be transferred between the AMF 115 and the UE 105 using a 5G Non-Access Stratum (NAS) protocol. The LPP and/or NPP protocol may be used to support positioning of the UE 105 using UE-assisted and/or UE-based position methods such as A-GNSS, RTK, OTDOA and/or E-CID. The NRPPa protocol may be used to support positioning of the UE 105 using network-based position methods such as E-CID (e.g., when used with measurements obtained by the gNB 110a, 110b or the ng-eNB 114) and/or may be used by the LMF 120 to obtain location related information from the gNBs 110a, 110b and/or the ng-eNB 114, such as parameters defining directional SS transmissions from the gNBs 110a, 110b, and/or the ng-eNB 114.

With a UE-assisted position method, the UE 105 may obtain location measurements and send the measurements to a location server (e.g., the LMF 120) for computation of a location estimate for the UE 105. For example, the location measurements may include one or more of a Received Signal Strength Indication (RSSI), Round Trip signal propagation Time (RTT), Reference Signal Time Difference (RSTD), Reference Signal Received Power (RSRP) and/or Reference Signal Received Quality (RSRQ) for the gNBs 110a, 110b, the ng-eNB 114, and/or a WLAN AP. The location measurements may also or instead include measurements of GNSS pseudorange, code phase, and/or carrier phase for the SVs 190-193.

With a UE-based position method, the UE 105 may obtain location measurements (e.g., which may be the same as or similar to location measurements for a UE-assisted position method) and may compute a location of the UE 105 (e.g., with the help of assistance data received from a location server such as the LMF 120 or broadcast by the gNBs 110a, 110b, the ng-eNB 114, or other base stations or APs).

With a network-based position method, one or more base stations (e.g., the gNBs 110a, 110b, and/or the ng-eNB 114) or APs may obtain location measurements (e.g., measurements of RSSI, RTT, RSRP, RSRQ or Time Of Arrival (TOA) for signals transmitted by the UE 105) and/or may receive measurements obtained by the UE 105. The one or more base stations or APs may send the measurements to a location server (e.g., the LMF 120) for computation of a location estimate for the UE 105.

Information provided by the gNBs 110a, 110b, and/or the ng-eNB 114 to the LMF 120 using NRPPa may include timing and configuration information for directional SS transmissions and location coordinates. The LMF 120 may provide some or all of this information to the UE 105 as assistance data in an LPP and/or NPP message via the NG-RAN 135 and the 5GC 140.

An LPP or NPP message sent from the LMF 120 to the UE 105 may instruct the UE 105 to do any of a variety of things depending on desired functionality. For example, the LPP or NPP message could contain an instruction for the UE 105 to obtain measurements for GNSS (or A-GNSS), WLAN, E-CID, and/or OTDOA (or some other position method). In the case of E-CID, the LPP or NPP message may instruct the UE 105 to obtain one or more measurement quantities (e.g., beam ID, beam width, mean angle, RSRP, RSRQ measurements) of directional signals transmitted within particular cells supported by one or more of the gNBs 110a, 110b, and/or the ng-eNB 114 (or supported by some other type of base station such as an eNB or WiFi AP). The UE 105 may send the measurement quantities back to the LMF 120 in an LPP or NPP message (e.g., inside a 5G NAS message) via the serving gNB 110a (or the serving ng-eNB 114) and the AMF 115.

As noted, while the communication system 10 is described in relation to 5G technology, the communication system 10 may be implemented to support other communication technologies, such as GSM, WCDMA, LTE, etc., that are used for supporting and interacting with mobile devices such as the UE 105 (e.g., to implement voice, data, positioning, and other functionalities). In some such embodiments, the 5GC 140 may be configured to control different air interfaces. For example, the 5GC 140 may be connected to a WLAN using a Non-3GPP InterWorking Function (N3IWF, not shown FIG. 1) in the 5GC 150. For example, the WLAN may support IEEE 802.11 WiFi access for the UE 105 and may comprise one or more WiFi APs. Here, the N3IWF may connect to the WLAN and to other elements in the 5GC 140 such as the AMF 115. In some embodiments, both the NG-RAN 135 and the 5GC 140 may be replaced by one or more other RANs and one or more other core networks. For example, in an EPS, the NG-RAN 135 may be replaced by an E-UTRAN containing eNBs and the 5GC 140 may be replaced by an EPC containing a Mobility Management Entity (MME) in place of the AMF 115, an E-SMLC in place of the LMF 120, and a GMLC that may be similar to the GMLC 125. In such an EPS, the E-SMLC may use LPPa in place of NRPPa to send and receive location information to and from the eNBs in the E-UTRAN and may use LPP to support positioning of the UE 105. In these other embodiments, positioning of the UE 105 using directional PRSs may be supported in an analogous manner to that described herein for a 5G network with the difference that functions and procedures described herein for the gNBs 110a, 110b, the ng-eNB 114, the AMF 115, and the LMF 120 may, in some cases, apply instead to other network elements such eNBs, WiFi APs, an MME, and an E-SMLC.

As noted, in some embodiments, positioning functionality may be implemented, at least in part, using the directional SS beams, sent by base stations (such as the gNBs 110a, 110b, and/or the ng-eNB 114) that are within range of the UE whose position is to be determined (e.g., the UE 105 of FIG. 1). The UE may, in some instances, use the directional SS beams from a plurality of base stations (such as the gNBs 110a, 110b, the ng-eNB 114, etc.) to compute the UE's position.

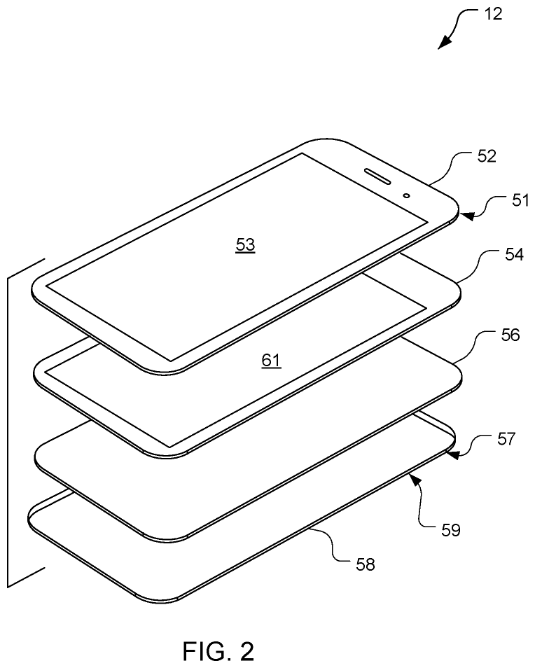

Referring also to FIG. 2, a mobile device 12, which is an example of the UE 105, shown in FIG. 1 includes a top cover 52, a display layer 54, a printed circuit board (PCB) layer 56, and a bottom cover 58. The mobile device 12 as shown may be a smartphone or a tablet computer but the discussion is not limited to such devices. The top cover 52 includes a screen 53. The bottom cover 58 has a bottom surface 59 and sides 51, 57 of the top cover 52 and the bottom cover 58 provide an edge surface. The top cover 52 and the bottom cover 58 comprise a housing that retains the display layer 54, the PCB layer 56, and other components of the mobile device 12 that may or may not be on the PCB layer 56. For example, the housing may retain (e.g., hold, contain) antenna systems, front-end circuits, an intermediate-frequency circuit, and a processor discussed below. The housing may be substantially rectangular, having two sets of parallel edges in the illustrated embodiment, and may be configured to bend or fold. In this example, the housing has rounded corners, although the housing may be substantially rectangular with other shapes of corners, e.g., straight-angled (e.g., 45°) corners, 90°, other non-straight corners, etc. Further, the size and/or shape of the PCB layer 56 may not be commensurate with the size and/or shape of either of the top or bottom covers or otherwise with a perimeter of the device. For example, the PCB layer 56 may have a cutout to accept a battery. Embodiments of the PCB layer 56 other than those illustrated may be implemented.

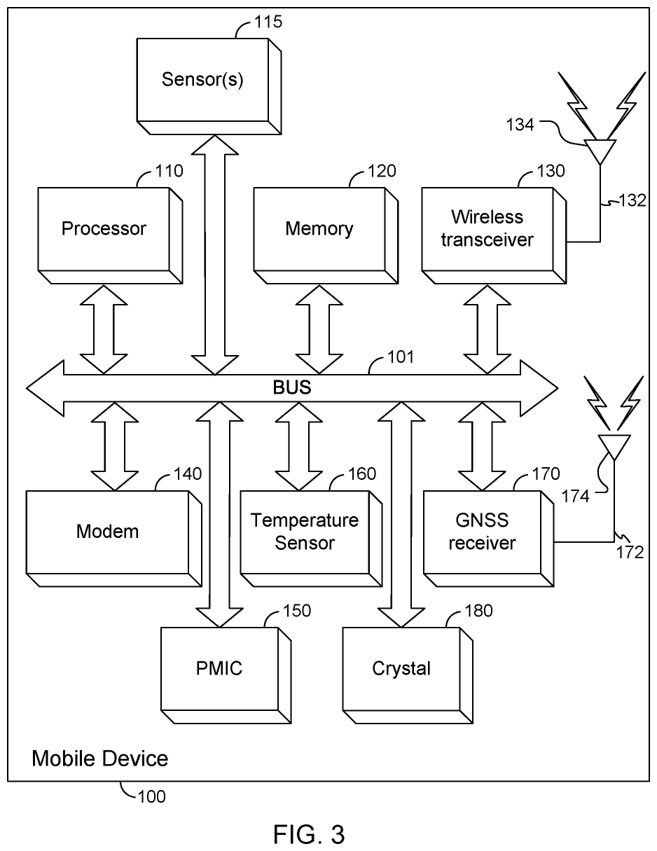

Referring also to FIG. 3, the mobile device 100, which is an example of the UE 105 shown in FIG. 1, may include a computer system including a general-purpose processor 110, one or more sensors 115, a memory 120, a wireless transceiver 130, a modem 140, a power management integrated circuit (PMIC) 150, a temperature sensor 160, a GNSS receiver 170, and a crystal 180 connected to each other by a bus 101. The connection to the bus 101 is for functional illustration as one or more of these devices may not be physically connected directly to the bus 101, e.g., being connected to the bus 101 through one or more of the other devices. The wireless transceiver 130 is connected by a line 132 to an antenna 134 for sending and receiving communications to/from the base stations 110a, 110b, 114 shown in FIG. 1. The GNSS receiver 170 is connected by a line 172 to an antenna 174 for receiving location signals (signals from which, at least in part, location can be determined) from the satellites 190-193 shown in FIG. 1. The processor 110 may include one or more intelligent devices, e.g., a central processing unit (CPU), a graphics processing unit (GPU), a microcontroller, an application specific integrated circuit (ASIC), an application processor, etc. The memory 120 is a non-transitory storage device that includes random access memory (RAM) and read-only memory (ROM). The memory 120 stores processor-readable software code containing instructions for controlling the processor 110 to perform functions described herein (although the description may read that the software performs the function(s)). The functions implement a positioning system. The software can be loaded onto the memory 120 by being downloaded via a network connection, uploaded from a disk, etc. The software may be processor-executable code, or may not be directly executable, e.g., requiring compiling before execution.

The sensor(s) 115 may include, for example, one or more inertial sensors, one or more magnetometers, and/or one or more environment sensors. An inertial measurement unit (IMU) may comprise, for example, one or more accelerometers (e.g., collectively responding to acceleration of the mobile device 100 in three dimensions) and/or one or more gyroscopes. The sensor(s) 115 may include one or more magnetometers to determine orientation (e.g., relative to magnetic north and/or true north) that may be used for any of a variety of purposes, e.g., to support one or more compass applications. The environment sensor(s) may comprise, for example, one or more temperature sensors, one or more barometric pressure sensors, one or more ambient light sensors, one or more camera imagers, and/or one or more microphones, etc. The sensor(s) 115 may generate analog and/or digital signals indications of which may be stored in the memory 120 and processed by the processor 110 in support of one or more applications such as, for example, applications directed to positioning and/or navigation operations. For example, the sensor(s) 115 may be used in relative location measurements, relative location determination, motion determination, etc. Information detected by the sensor(s) 115 may be used for motion detection, relative displacement, dead reckoning, sensor-based location determination, and/or sensor-assisted location determination. The sensor(s) 115 may be useful to determine whether the mobile device 100 is fixed (stationary) or mobile and/or whether to report certain useful information to a server regarding the mobility of the mobile device 100. For relative positioning information, the sensors/IMU can be used to determine an angle and/or orientation of another device with respect to the mobile device 100.

The PMIC 150 is connected and configured to provide power to components of the mobile device 100 and to provide voltage to the crystal 180. The PMIC 150 includes an oscillator 152, and an analog-to-digital converter (ADC) 154. The oscillator 152 is connected to the crystal 180 by voltage lines 155. The ADC 154 may be connected to the temperature sensor 160 and to the CPU 112, and configured to convert analog indications of temperature (e.g., voltages) from the sensor 160 to digital indications of the temperature that the ADC 154 provides to the CPU 112.

The crystal 180 is configured to produce a reference signal with a reference frequency, e.g., for use in acquiring signals received by the antenna 174. The reference frequency produced by the crystal 180 is a function of temperature, i.e., the reference frequency is dependent upon the temperature of the crystal 180 and thus will change with changes in the temperature of the crystal 180. For example, the frequency of the crystal 180 as a function of temperature can be represented by an FT (frequency-temperature) curve according to

f(t)=c₃(t−t₀)³+c₂(t−t₀)²+c₁(t−t₀)+c₀ (1)

where c₀, c₁, c₂, c₃ are temperature-gradient constants, with c₁ between 0.1 ppm/° C. and 0.40 ppm/° C., t₀=30° C., and t being the present actual crystal temperature.

Various components of the mobile device 100 may emit heat and affect the temperature of the crystal 180. For example, a CPU of the processor 110, a 114 of the processor 110, the PMIC 150, a power amplifier, the GNSS receiver 170, etc. may each contribute heat to the crystal 180. The components may provide various amounts of heat, may be disposed at various locations within the mobile device 100 and at various distances from the crystal 180. Thus, the different components may have different effects on the temperature of the crystal 180, making determination of the temperature of the crystal difficult. The temperature sensor 160 is thus connected to the crystal 180, as discussed in more detail below, to determine the temperature of the crystal 180 as affected by multiple heat sources at various locations.

The software in the memory 120 may be configured to enable the processor 110 to communicate with the temperature sensor 160, to obtain temperature indications relevant to the crystal 180. The processor 110 may use these temperature indications to estimate a temperature of the crystal 180 and to estimate a frequency of a signal produced by the crystal 180, e.g., according to Eqn. (1). For example, the CPU 112 may be configured to use the indications of temperature from the ADC 154 to calculate an estimated temperature of the crystal 180 and to determine a frequency of the crystal 180 based on the estimated temperature. The CPU 112 may determine the estimated temperature in one or more of a variety of ways. As examples, the CPU 112 may use the temperature indicated by the sensor 160 as the estimated temperature of the crystal 180, or may calculate the estimated temperature based on a conversion formula (e.g., empirically developed) for the estimated temperature of the crystal 180 as a function of the temperature from the sensor 160, or may determine the estimated temperature based on a look-up table of crystal temperatures and temperatures measured by the sensor 160. Still other techniques for determining the estimated temperature may be used. The CPU 112 may average multiple determined estimated temperatures. The CPU 112 may determine a temperature-affected frequency of the crystal 180 using the estimated temperature, e.g., by calculating the frequency using Eqn. (1), or by using a look-up table of estimated crystal temperatures and temperature-affected frequencies, or by another technique.

The processor 110 may be configured to compensate for the determined temperature-affected frequency of the crystal 180. For example, the processor 110 may adjust a count value for an action dependent upon a cycle count of the crystal frequency. For example, if the crystal 180 at a baseline temperature has a frequency of 50 KHz and is being used for a clock, and the temperature-affected frequency is determined to be 55 KHz, then a count value for indicating that a second has passed may be adjusted by the processor 110 from 50,000 cycles to 55,000 cycles. This is but one example, and numerous other examples of compensating for the temperature-affected frequency may be implemented, e.g., by the processor 110.

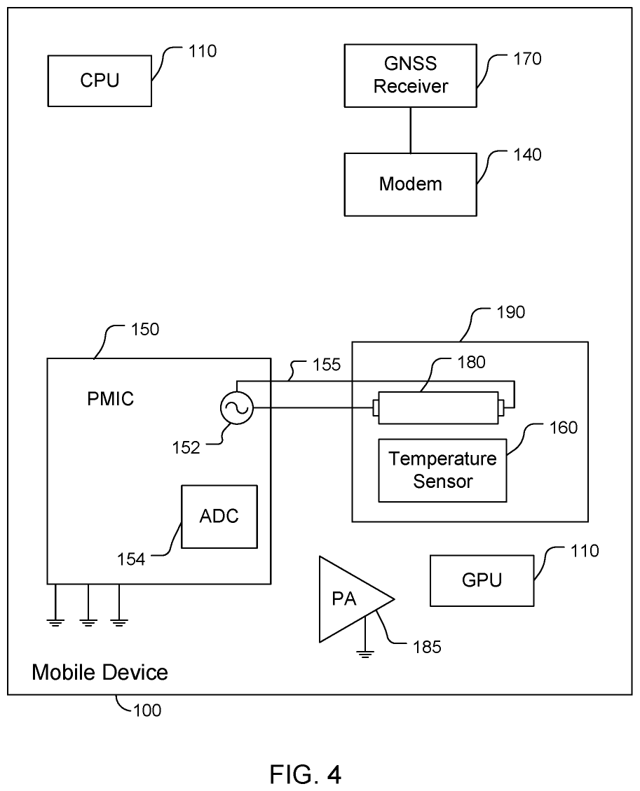

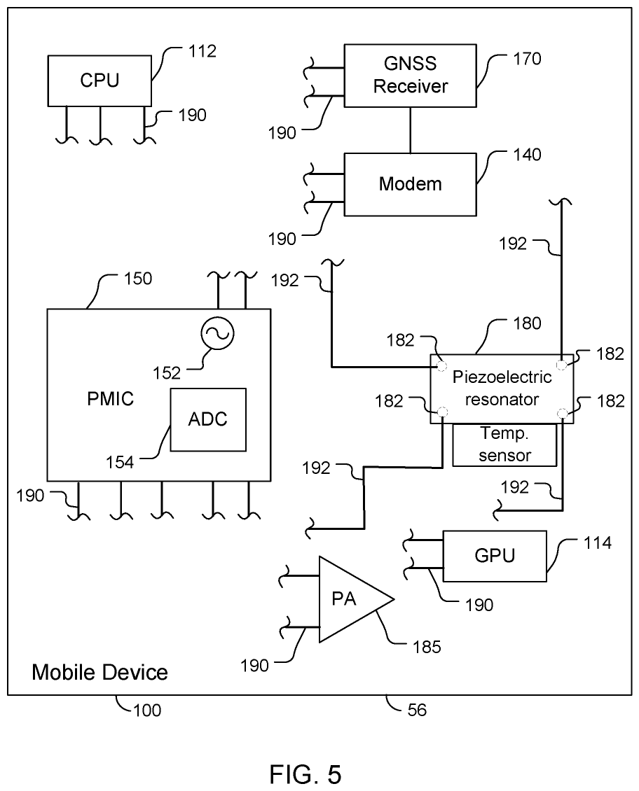

Referring also to FIGS. 4 and 5, an example of the mobile device 100 includes the PMIC 150, the crystal 180, the GNSS receiver 170, the modem 140, the temperature sensor 160, a CPU 112 of the processor 110, a GPU 114 of the processor 110, and a power amplifier 185 disposed on, or part of, the PCB 56. In this example, the crystal 180 and the temperature sensor 160 are disposed adjacent to each other. Also in this example, the CPU 112, the GPU 114, the GNSS receiver 170, the modem 140, the PMIC 150, and the power amplifier 185 are disposed at various locations in the mobile device 100 and at various distances from the crystal 180. The components shown are connected to electrically-conductive traces 190, 192 that connect the components to each other as appropriate for conveying signals (e.g., communication signals, power, etc.) within the mobile device 100. The traces 190, 192 also convey heat such that the crystal 180 receives heat from other components of the mobile device 100 through the traces 192 connected to the crystal 180, here connected to four connectors 182 (e.g., pins) of the crystal 180. The traces 190, 192 convey heat from other components disposed at various locations in the mobile device 100. Heat may also be conveyed to the crystal 180 through other means such as through a substrate of the PCB 56 and through air within the mobile device 100. A significant amount, however, of heat received by the crystal 180 may be received via the traces 192. For example, as much as 95% of heat received by the crystal 180 may be received via the traces 192 connected to the connectors 182. The amount of heat received by the crystal 180 via the traces 192 may vary depending on the configuration of the mobile device 100 (e.g., locations of the components, the configuration of the traces 192 connected to the connectors 182, etc.). Heat may be transferred to the traces 192 indirectly from components of the mobile device 100, e.g., through the substrate of the PCB 56 and/or through the air (e.g., from one or more of the traces 190 that are disposed proximate to one or more of the traces 192 and/or proximate to one or more of the other components of the mobile device 100). For example, heat from the PMIC 150 may be conveyed to the crystal 180 faster and more efficiently than ambient heat transfer (through the air) or heat transfer through a ground conductor of the PCB 56, e.g., shared by the crystal 180 and one or more other components such as the PMIC 150, the power amplifier 185, the CPU 112, the GPU 114, the modem 140, and/or the GNSS receiver 170. Indeed, heat conveyed through the ground conductor and/or a substrate of the PCB 56 may primarily reach the crystal 180 via the traces 192.

The temperature sensor 160 is configured and disposed to determine a temperature associated with the crystal 180. The sensor 160 is preferably disposed such that the sensor 160 experiences a similar environmental temperature as the crystal 180, including influences from the crystal 180, and will thus, in a steady-state environment, be at or near (e.g., within about 1° C. of) the temperature of the crystal 180. For example, the sensor 160 can be a thermistor disposed adjacent to, here in physical contact with, the crystal 180 to measure/sense the temperature in the area of the crystal 180. The temperature sensor 160 could be adjacent to, but separate from, i.e., physically displaced from, the crystal 180. For example, the temperature sensor 160 could be displaced from the crystal 180 by a distance between 1 μm and 1 mm. Such close proximity may help the temperature sensor 160 receive nearly the same amount of ambient heat as the crystal 180 receives.

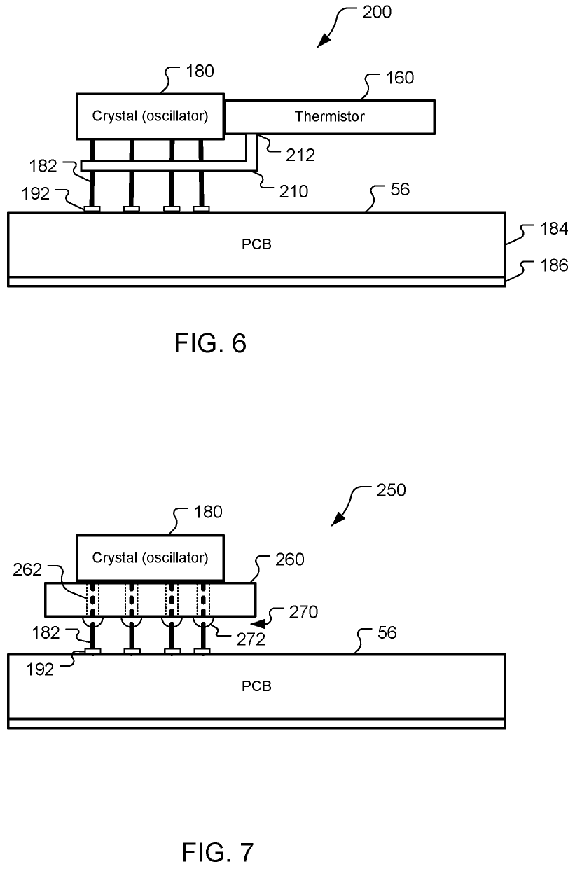

Referring also to FIG. 6, in a thermal coupler configuration 200, the temperature sensor 160 is in physical contact with the crystal 180 and is thermally coupled to the connectors 182. Thermally coupling the temperature sensor 160 (here, a thermistor) helps the temperature sensor 160 receive a similar amount of heat as that received by the crystal 180. Heat may be transferred from heat sources (see FIG. 5) through a substrate 184 of the PCB 56, through a ground conductor 186 of the PCB 56, and/or via the traces 190, 192 to the connectors 182. In this example, a thermal coupler 210 thermally couples the temperature sensor 160 to all four of the connectors 182 connecting the crystal 180 to respective traces 192 of the PCB 56. The thermal coupler 210 cause heat in the connectors 182 to be shared between the crystal 180 and the temperature sensor 160 such that the crystal 180 and the temperature sensor 160 may be similarly heated (e.g., may be within 1° C. of each other). Here, the thermal coupler 210 thermally couples all of the connectors 182 to each other and to the temperature sensor. In this example, the thermal coupler 210 comprises a thermally-conductive glue, although other thermally-conductive materials may be used. The thermal coupler 210 is electrically insulative to isolate the connectors 182 from each other electrically. The thermal coupler 210 may thermally couple the connectors to a single input 212 of the temperature sensor 160. Other configurations of thermal couplers may, however, be used. For example, a thermal coupler could couple one or more of the connectors 182 to the temperature sensor 160 but not to one or more other ones of the connectors 182. As another example, a thermal coupler could thermally couple different ones of the connectors 182 to different physical portions of the temperature sensor 160. The temperature sensor 160 may internally aggregate the heat received from such a thermal coupler to provide a single measure of temperature.

Because the connectors 182 may be the primary sources of heat received by the crystal 180, and because the temperature sensor 160 is thermally coupled to the connectors 182, the temperature sensor 160 may receive a very similar amount of heat as does the crystal 180, and with little to no lag relative to the crystal 180. Thus, the temperature measured by the temperature sensor 160 may be very similar to that of the crystal 180, with very little (possibly negligible) lag between temperature changes to the crystal 180 and temperature changes measured by the temperature sensor 160.

Referring also to FIG. 7, another thermal coupler configuration 250 is shown. In the configuration 250, a temperature sensor 260 overlaps with and is in physical contact with the crystal 180, and is disposed between the crystal 180 and the PCB 56. The temperature sensor 260 defines passageways 262 that receive the connectors 182, allowing the connectors 182 to pass through the temperature sensor 260 to the crystal 180. A thermal coupler 270 includes blobs 272, e.g., of thermally-conductive glue, that each thermally couples a respective one of the connectors 182 to the temperature sensor 260 separately. The temperature sensor 260 may be configured to aggregate, internally, the heat received from the connectors 182 and to provide a single measure of temperature of the aggregated heat.

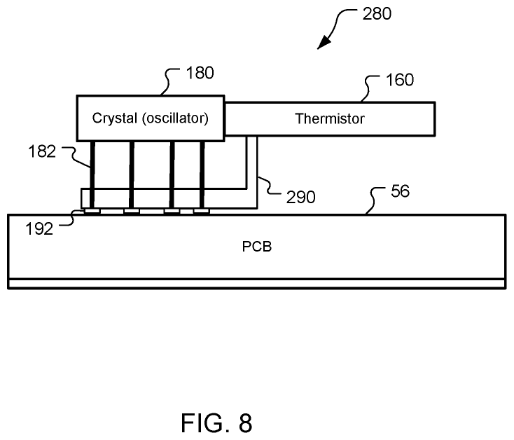

Other configurations of thermal couplers may be used. For example, the thermal coupler could thermally couple at least two, e.g., all, of the connectors 182 to each other in addition to thermally coupling the connectors to the temperature sensor 260. As another example, referring also to FIG. 8, a thermal coupler configuration 280 includes a thermal coupler 290 that is thermally connected to the traces 192 to which the connectors 182 are electrically connected. The thermal coupler 280 may not be directly physically connected to one or more, or any, of the connectors 182. Thus, the thermal coupler 290 may be thermally coupled to the connectors 182 via the traces 192. Still other thermal coupler configurations may be used.

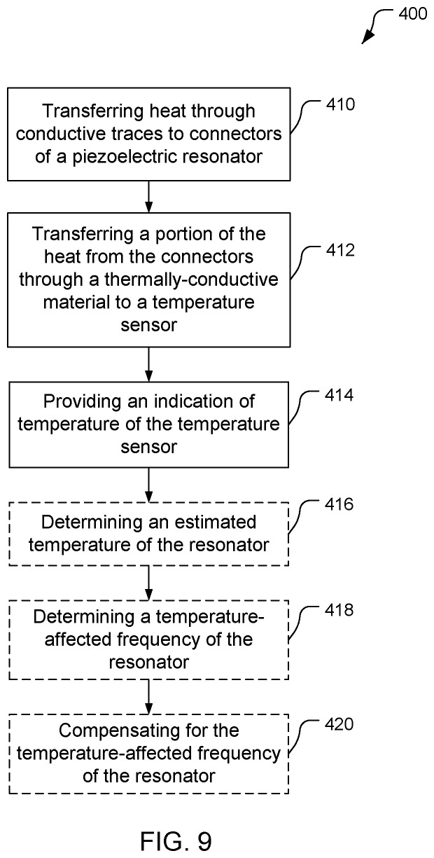

Referring to FIG. 9, with further reference to FIGS. 1-8, a method 400 of providing an indication of a temperature associated with a piezoelectric resonator includes the stages shown. The method 400 is, however, an example only and not limiting. The method 400 can be altered, e.g., by having stages added, removed, rearranged, combined, and/or performed concurrently. For example, stages 416, 418, and 420 are optional.

At stage 410, the method 400 includes transferring heat through conductive traces to connectors of a piezoelectric resonator. For example, heat may be transferred through multiple traces 190, 192 of the printed circuit board 56 to the connectors 182 that are connected to the crystal 180, with the traces 190, 192 and the connectors 182 being electrically and thermally conductive. Heat may be produced by one or more components of the mobile device 100 and transferred through the traces 190, 192, through the air, and/or through a substrate of the PCB 56 to the traces 192. The traces 190, 192 may provide means for transferring heat from heat sources of a PCB (e.g., on or in the PCB 56) to connectors that are connected to a piezoelectric resonator. The means for transferring heat may also comprise the substrate 184 of the PCB 56 and/or the ground conductor 186 of the PCB 56.

At stage 412, the method 400 includes transferring a portion of the heat from the connectors through a thermally-conductive, electrically-insulative material to a thermistor. For example, some heat in the connectors 182 is transferred through the thermal coupler 210, 270, 290 to the temperature sensor 160, 260, and some of the heat is transferred from the connectors 182 to the crystal 180. The thermal coupler 210, 270, 290 may provide thermal means for transferring heat from the connectors to temperature means for measuring, and providing an indication of, temperature.

At stage 414, the method 400 includes providing an indication of temperature of a temperature sensor. For example, the temperature sensor 160, 260 measures a temperature and provides an indication of this temperature. The temperature is representative of the temperature of the crystal 180 as heat is coupled from the connectors 182 of the crystal 180, from which the crystal 180 typically receives the majority of heat received by the crystal 180. The heat received by the temperature sensor 160, 260 may be aggregated and the temperature sensor 160, 260 may provide a single indication of a single temperature due to the aggregated heat. The heat may be aggregated before being received by the temperature sensor 160, 260, e.g., being aggregated in the thermal coupler 210, 290, or may be aggregated within the temperature sensor 160, 260. The sensor 160, 260 may provide an analog voltage proportional to the temperature to the ADC 154 and the ADC 154 may provide a digital indication of the temperature to the processor 110 (e.g., to the CPU 112). The temperature sensor 160, 260, e.g., a thermistor, may provide temperature means for measuring, and providing an indication of, temperature. The ADC 154 may provide part of the temperature means.

At stage 416, the method 400 includes determining an estimated temperature of the piezoelectric resonator, i.e., the crystal 180. For example, the processor 110 may use the temperature sensed by the temperature sensor 160, 260 as the estimated crystal temperature. Alternatively, the processor 110 may determine the estimated crystal temperature using a formula relating the temperature indicated by the temperature sensor 160, 260 to crystal temperature or a look-up table relating the temperature indicated by the temperature sensor 160, 260 to crystal temperature. For example, such a formula or look-up table may be based on experimental data including measurements of the crystal temperature and concurrent temperature indications from the sensor 160, 260. The processor 110, possibly in combination with the memory 120, and the temperature sensor 160, 260 may provide means for determining the estimated temperature of the piezoelectric resonator.

At stage 418, the method 400 includes determining a temperature-affected frequency of the piezoelectric resonator. For example, the processor 110 may calculate the frequency of the crystal 180 using the determined estimated temperature of the crystal 180 as the present actual crystal temperature in Eqn. (1). Alternatively, the processor 110 could use a look-up table of crystal temperatures and crystal frequencies, and determine the temperature-affected frequency of the resonator to be the frequency corresponding to the temperature nearest to the estimated temperature of the crystal 180. Alternatively, the processor 110 may determine a change in the estimated crystal frequency without determining the estimated crystal frequency itself. The processor 110, possibly in combination with the memory 120, may provide means for determining the temperature-affected frequency of the piezoelectric resonator.

At stage 420, the method 400 includes compensating for the temperature-affected frequency of the resonator. For example, the processor 110 may use the temperature-affected frequency of the crystal 180 to compensate for changes of the reference frequency provided by the crystal 180 for processing data or signals (e.g., acquiring signals) in the mobile device 100. For example, the reference frequency or change in the reference frequency from the crystal 180 may be used to adjust a frequency used to obtain, acquire, or maintain a GNSS fix to determine location of the mobile device 100. For example, the reference frequency or change in the reference frequency may be used to produce an adjustment of a multiplier of a local oscillator in the mobile device. The reference frequency or change in the reference frequency may be used to digitally rotate frequencies, e.g., of received GNSS signals, to compensate for the actual value of the reference frequency compared to an expected value of the reference frequency. Also or alternatively, the reference frequency may be used to adjust a counter for a clock. The processor 110, possibly in combination with the memory 120, may provide means for compensating for the temperature-affected frequency of the resonator.

### OTHER CONSIDERATIONS

Having described several example configurations, other examples or implementations including various modifications, alternative constructions, and equivalents may be used without departing from the spirit of the disclosure. For example, due to the nature of software and computers, functions described above can be implemented using software executed by a processor, hardware, firmware, hardwiring, or a combination of any of these. Features implementing functions may also be physically located at various positions, including being distributed such that portions of functions are implemented at different physical locations. Elements discussed may be components of a larger system, wherein other rules may take precedence over or otherwise modify the application of the invention. Also, a number of operations may be undertaken before, during, or after above-discussed elements or operations are considered. Examples of methods discussed may be implemented by hardware, software, firmware, middleware, microcode, hardware description languages, or any combination thereof. When implemented in software, firmware, middleware, or microcode, the program code or code segments to perform the tasks may be stored in a non-transitory computer-readable medium such as a storage medium. Accordingly, the above description does not bound the scope of the claims.

As used herein, “or” as used in a list of items prefaced by “at least one of” or prefaced by “one or more of” indicates a disjunctive list such that, for example, a list of “at least one of A, B, or C,” or a list of “one or more of A, B, or C,” or “A, B, or C, or a combination thereof” means A or B or C or AB or AC or BC or ABC (i.e., A and B and C), or combinations with more than one feature (e.g., AA, AAB, ABBC, etc.).

As used herein, unless otherwise stated, a statement that a function or operation is “based on” an item or condition means that the function or operation is based on the stated item or condition and may be based on one or more items and/or conditions in addition to the stated item or condition.

The terms “processor-readable medium,” “machine-readable medium,” and “computer-readable medium,” or the like as used herein, refer to any medium that participates in providing data that causes a machine to operate in a specific fashion. Using a computer system, various processor-readable media might be involved in providing instructions/code to processor(s) for execution and/or might be used to store and/or carry such instructions/code (e.g., as signals). In many implementations, a processor-readable medium is a physical and/or tangible storage medium. Such a medium may take many forms, including but not limited to, non-volatile media and volatile media. Non-volatile media include, for example, optical and/or magnetic disks. Volatile media include, without limitation, dynamic memory.

Common forms of physical and/or tangible computer-readable media include, for example, hard disk, magnetic tape, or any other magnetic medium, a CD-ROM, any other optical medium, a RAM, a PROM, EPROM, a FLASH-EPROM, any other memory chip or cartridge, or any other medium from which a computer can read instructions and/or code.

Specific details are given in the description to provide a thorough understanding of example configurations (including implementations). However, configurations may be practiced without these specific details. For example, well-known circuits, processes, algorithms, structures, and techniques have been shown without unnecessary detail in order to avoid obscuring the configurations. This description provides example configurations only, and does not limit the scope, applicability, or configurations of the claims. Rather, the preceding description of the configurations provides a description for implementing described techniques. Various changes may be made in the function and arrangement of elements without departing from the spirit or scope of the disclosure.

Components, functional or otherwise, shown in the figures and/or discussed herein as being connected or communicating with each other are communicatively coupled unless otherwise noted. That is, they may be directly or indirectly connected to enable communication between them.

What is claimed is:

1. A mobile device comprising:
a printed circuit board comprising circuit components and a plurality of traces that are electrically and thermally conductive;
a piezoelectric resonator coupled to a subset of the traces by a plurality of connectors that are electrically and thermally conductive;
a temperature sensor configured to provide an indication of temperature; and
a thermal coupler coupled to the temperature sensor and to the plurality of connectors, the thermal coupler being thermally conductive and electrically insulative.

2. The mobile device of claim 1, wherein the thermal coupler is configured and disposed to thermally couple at least two of the plurality of connectors to each other.

3. The mobile device of claim 2, wherein the thermal coupler is configured and disposed to thermally couple all of the plurality of connectors to each other.

4. The mobile device of claim 1, wherein the thermal coupler is configured and disposed to thermally couple each of the plurality of connectors to the temperature sensor separately.

5. The mobile device of claim 1, wherein the temperature sensor is in physical contact with the piezoelectric resonator.

6. The mobile device of claim 1, wherein the temperature sensor is disposed adjacent to, and separate from, the piezoelectric resonator.

7. The mobile device of claim 1, wherein at least a portion of the temperature sensor is disposed between the printed circuit board and the piezoelectric resonator.

8. The mobile device of claim 1, wherein the temperature sensor is configured and connected to the thermal coupler to provide a single measure of temperature corresponding to heat received from the thermal coupler.

9. The mobile device of claim 1, further comprising a processor communicatively coupled to the temperature sensor and configured to determine a frequency of the piezoelectric resonator based on the indication of temperature.

10. A method comprising:
transferring heat through a plurality of traces of a printed circuit board to a plurality of connectors that are connected to a piezoelectric resonator, the plurality of traces being electrically and thermally conductive, and the plurality of connectors being electrically and thermally conductive;
transferring a portion of the heat from the plurality of connectors through a thermally-conductive, electrically-insulative material to a temperature sensor; and
providing an indication of temperature by the temperature sensor.

11. The method of claim 10, wherein the portion of the heat is transferred from the plurality of connectors to a single input of the temperature sensor.

12. The method of claim 11, wherein the temperature sensor provides a single measure of temperature corresponding to the portion of the heat transferred to the temperature sensor.

13. The method of claim 10, further comprising determining a frequency of the piezoelectric resonator based on the indication of temperature.

14. An apparatus comprising:
a piezoelectric resonator;
temperature means for measuring, and providing an indication of, temperature;
means for transferring heat from a plurality of heat sources of a printed circuit board to a plurality of connectors that are connected to the piezoelectric resonator, the plurality of connectors being electrically and thermally conductive; and
thermal means for transferring a portion of the heat from the plurality of connectors to the temperature means, the thermal means being thermally conductive and electrically insulative.

15. The apparatus of claim 14, wherein the plurality of connectors comprises at least three connectors and wherein the thermal means thermally couple at least two of the plurality of connectors to each other.

16. The apparatus of claim 15, wherein the thermal means thermally couple all of the plurality of connectors to each other.

17. The apparatus of claim 14, wherein the thermal means thermally couple each of the plurality of connectors to the temperature means separately.

18. The apparatus of claim 14, wherein the temperature means are in physical contact with the piezoelectric resonator.

19. The apparatus of claim 14, wherein the temperature means are disposed adjacent to, and separate from, the piezoelectric resonator.

20. The apparatus of claim 14, wherein at least a portion of the temperature means is disposed between the printed circuit board and the piezoelectric resonator.

21. The apparatus of claim 14, wherein the thermal means are for transferring the portion of the heat from the plurality of connectors to a single input of the temperature means.

22. The apparatus of claim 14, further comprising means, communicatively coupled to the temperature means, for determining a frequency of the piezoelectric resonator based on the indication of temperature.
